(19) United States
(12) Patent Application Publication
(10) Pub. No.: US 2026/0011305 A1
(43) Pub. Date: Jan. 8, 2026

(54) DISPLAY DEVICE AND DISPLAY PANEL

(71) Applicant: LG Display Co., Ltd., Seoul (KR)

(72) Inventors: DoYoung JUNG, Paju-si (KR); Byeong-Seong SO, Paju-si (KR); Seung Hyun SONG, Paju-si (KR)

(73) Assignee: LG Display Co., Ltd., Seoul (KR)

(21) Appl. No.: 19/195,343

(22) Filed: Apr. 30, 2025

(30) Foreign Application Priority Data
Jul. 8, 2024 (KR) 10-2024-0089699

(51) Int. Cl. G09G 3/3233

(52) U.S. Cl. CPC G09G 3/3233; G09G 2300/0426; G09G 2300/0852; G09G 2300/0861; G09G 2310/06; G09G 2310/08; G09G 2320/0233; G09G 2330/12

(57) ABSTRACT

A display panel and a display device including the display panel are discussed. The display device in some examples can include a light emitting element included in each of a plurality of subpixels, a subpixel circuit configured to drive the light emitting element, a reference voltage line connected to a pixel group including a plurality of subpixel circuits, and a load control transistor electrically connecting the pixel group and the reference voltage line during a period in which a gate signal is applied to the pixel group.

### CROSS-REFERENCE TO RELATED APPLICATION

This application claims priority to Korean Patent Application No. 10-2024-0089699, filed on Jul. 8, 2024 in the Korean Intellectual Property Office, the entire contents of which is hereby expressly incorporated by reference for all purposes as if fully set forth herein into the present application.

### BACKGROUND

### Field

The present disclosure relates to a display device and a display panel, and more particularly, to a display device and a display panel that include a structure of reducing a time of sensing one or more characteristic values of a driving transistor included in a subpixel.

### Discussion of the Related Art

As display devices for displaying images using digital data, liquid crystal display (LCD) devices using liquid crystals, organic light emitting display devices using organic light emitting diodes (OLED), and the like are widely used.

Among these display devices, organic light emitting display devices using an organic light emitting diode, which is a self-emission element, have the features of fast response speed, high contrast ratio, high luminous efficiency, high luminance, wide viewing angle, and the like. For example, the light emitting diode can be implemented with an inorganic or organic material.

Organic light emitting display devices can include an organic light emitting diode disposed in each of a plurality of subpixels disposed in a display panel. Image displaying by light emitted from the organic light emitting diodes can be performed by controlling current flowing through, or voltage applied to, the organic light emitting diodes. In this way, as luminance from each subpixel is controlled, the organic light emitting display devices can display images.

In these organic light emitting display devices, each subpixel disposed in the display panel can include a light emitting element and a driving transistor for driving the light emitting element. The characteristic values such as a threshold voltage, mobility, and the like of the driving transistor of each subpixel can be changed by aging of the driving transistor through use, or a difference in characteristic values between transistors can occur due to a difference in driving times of subpixels. Such a change of characteristic values or a difference in characteristic values can cause a difference (non-uniformity) in luminance between the subpixels, which can degrade the leading image quality.

To address a difference in luminance between the subpixels, in the case of an OLED display device, work has been progressing on a technology for sensing one or more characteristic values such as a threshold voltage, mobility, and the like of a driving transistor and then, compensating for a change in one or more such characteristic values. In particular, one or more characteristic value of a driving transistor can be sensed in real time while image driving is performed, which is sometimes referred to as a real-time (RT) sensing process. In the case of the real-time sensing process, for example, the sensing process can be performed for one or more subpixels of one or more subpixel arrays for each blank period during an image driving period.

However, as the resolutions of display devices are increased, the display devices can suffer from a problem that a sensing time and a compensation time for a subpixel can increase. For example, sensing and compensation times can take 1 minute or more for a full high definition (FHD) display device, 5 minutes or more for a ultra high definition (UHD) display device, and 20 minutes or more for a quantum dot ultra high definition (QUHD) display device.

### SUMMARY OF THE DISCLOSURE

To address these issues and other limitations associated with the related art, inventors of the present application have invented a display device and a display panel that include a structure of reducing or controlling a time of sensing characteristic values of driving transistors included in subpixels of the display panel.

One or more aspects of the present disclosure can provide a display device and a display panel that include a structure capable of reducing or controlling a time of sensing characteristic values of driving transistors by reducing a load of a reference voltage line for sensing the characteristic values of the driving transistors.

One or more aspects of the present disclosure can provide a display device and a display panel that include a structure capable of reducing a time of sensing characteristic values of driving transistors by disposing a load control transistor between sensing transistors and a reference voltage line.

According to one or more example embodiments of the present disclosure, a display panel can include a light emitting element included in each of a plurality of subpixels, a subpixel circuit for driving the light emitting element, a reference voltage line connected to a pixel group including a plurality of subpixel circuits, and a load control transistor for electrically connecting the pixel group and the reference voltage line during a period in which a gate signal is applied to the pixel group.

According to one or more example embodiments of the present disclosure, a display device can include a display panel including a plurality of subpixels, and a driving circuit configured to drive the display panel, the display panel including a light emitting element included in each of a plurality of subpixels, a subpixel circuit for driving the light emitting element, a reference voltage line connected to a pixel group including a plurality of subpixel circuits, and a load control transistor for electrically connecting the pixel group and the reference voltage line during a period in which a gate signal is applied to the pixel group.

According to one or more aspects of the present disclosure, a display device and a display panel can provide an effect or advantage of reducing a time of sensing characteristic values of driving transistors included in subpixels.

According to one or more aspects of the present disclosure, a display device and a display panel can provide an effect or advantage of reducing a time of sensing characteristic values of driving transistors by reducing a load of a reference voltage line for sensing the characteristic values of the driving transistors.

According to one or more aspects of the present disclosure, a display device and a display panel can provide an effect or advantage of reducing a time of sensing characteristic values of driving transistors by disposing a load control transistor between sensing transistors and a reference voltage line.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example display device according to aspects of the present disclosure;

FIG. 2 illustrates an example system of the display device according to aspects of the present disclosure;

FIG. 3 illustrates an example equivalent circuit of each of subpixels included in a display panel according to aspects of the present disclosure;

FIG. 4 illustrates an example equivalent circuit of a subpixel having a one-gate driven structure in the display panel according to aspects of the present disclosure;

FIG. 5 illustrates an example compensation circuit for a subpixel SP included in the display device according to aspects of the present disclosure, and this subpixel SP can represent the subpixel SP in FIG. 3;

FIG. 6 illustrates an example first sensing mode used in the display device according to aspects of the present disclosure;

FIG. 7 illustrates an example second sensing mode used in the display device according to aspects of the present disclosure;

FIG. 8 illustrates an example reference voltage line sharing structure in the display panel according to aspects of the present disclosure;

FIG. 9 illustrates an example structure of the display panel according to aspects of the present disclosure;

FIG. 10 illustrates another example structure of the display panel according to aspects of the present disclosure;

FIG. 11 is an experimental graph showing a difference between characteristic value sensing times in the display panel according to aspects of the present disclosure;

FIG. 12 illustrates an example subpixel structure in the display panel according to aspects of the present disclosure; and

FIG. 13 illustrates signal waveforms for operating a subpixel circuit of FIG. 12.

### DETAILED DESCRIPTION OF THE EMBODIMENTS

Hereinafter, various embodiments of the present disclosure will be described in detail with reference to example drawings, where reference will be made in detail to example embodiments of the present disclosure, examples or aspects of which can be illustrated in the accompanying drawings. In the following description, the structures, implementations, methods, and operations described herein are not limited to the specific examples, aspects, and embodiments set forth herein and can be changed as is known in the art, unless otherwise specified. Like reference numerals designate like elements throughout, unless otherwise specified. Names of the respective elements used in the following explanations are selected only for convenience of writing the disclosure and can thus be different from those used in actual products. Further, in the following description of examples or embodiments of the present invention, detailed descriptions of well-known functions and components incorporated herein will be omitted when it is determined that the description can make the subject matter in some embodiments of the present invention rather unclear. Where the terms “comprise,” “have,” “include,” “contain,” “constitute,” “compose, “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can” and vice versa.

Hereinafter, various embodiments of the present disclosure will be described in detail with reference to the accompanying drawings. All the components of each display device and each display panel according to all embodiments of the present disclosure are operatively coupled and configured.

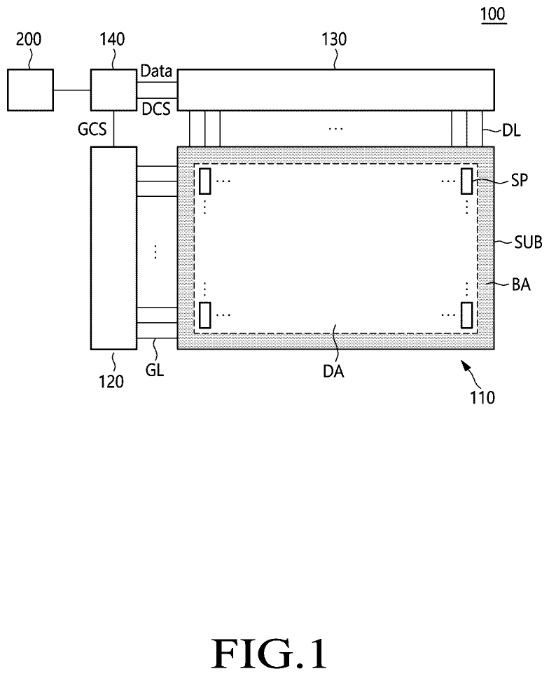

FIG. 1 illustrates an example display device according to aspects of the present disclosure.

Referring to FIG. 1, in one or more example embodiments, a display device 100 can include a display panel 110 and at least one driving circuit for driving the display panel 110.

The display panel 110 can include a display area DA in which one or more images can be displayed and a bezel area BA in which an image is not displayed. The bezel area BA can also be referred to as a non-display area, or a non-active area.

The display panel 110 can include a plurality of subpixels SP for displaying images. For example, the plurality of subpixels SP can be disposed in the display area DA. In one or more aspects, at least one subpixel SP can be disposed in the bezel area BA. The at least one subpixel SP disposed in the bezel area BA can be referred to as a dummy subpixel.

The display panel 110 can include a plurality of signal lines for driving the plurality of subpixels SP. For example, the plurality of signal lines can include a plurality of data lines DL and a plurality of gate lines GL. The signal lines can further include other signal lines, in addition to the plurality of data lines DL and the plurality of gate lines GL, according to the structure of the subpixels SP. For example, such signal lines can include driving voltage lines, reference voltage lines, and the like.

The plurality of data lines DL and the plurality of gate lines GL can intersect each other. Each of the plurality of data lines DL can extend in a first direction. Each of the plurality of gate lines GL can extend in a second direction different from the first direction. For example, the first direction can be a column or vertical direction, and the second direction can be a row or horizontal direction. Herein, the column direction and the row direction may not represent absolute directions, but can represent relative directions. For example, the column direction can be the vertical direction and the row direction can be the horizontal direction. In another example, the column direction can be the horizontal direction and the row direction can be the vertical direction.

The at least one driving circuit can include a data driving circuit 130 for driving a plurality of data lines DL and a gate driving circuit 120 for driving a plurality of gate lines GL. The at least one driving circuit can further include a timing controller 140 for controlling the data driving circuit 130 and the gate driving circuit 120.

The data driving circuit 130 can be a circuit for driving the plurality of data lines DL and can output data signals (which can be referred to as data voltages) corresponding to image signals to the plurality of data lines DL. The gate driving circuit 120 can be a circuit for driving the plurality of gate lines GL and can generate gate signals and supply the generated gate signals to the plurality of gate lines GL. The gate signals can include at least one scan signal and at least one emission signal.

The timing controller 140 can start to scan pixels according to respective timings set in each frame, and can control data driving at timings set for scanning corresponding one or more of the pixels. The timing controller 140 can convert image data received from an external device or system (e.g., a host system 200) to a data signal form readable by the data driving circuit 130, and then supply image data Data resulting from the converting to the data driving circuit 130.

The timing controller 140 can receive display driving control signals along with image data from the external host system 200. For example, the display driving control signals can include a vertical sync signal, a horizontal sync signal, an input data enable signal, a clock signal, and the like. However, aspects of the present disclosure are not limited thereto.

The timing controller 140 can generate data driving control signals DCS and gate driving control signals GCS based on the display driving control signals received from the host system 200. The timing controller 140 can control the driving operation and driving timing of the data driving circuit 130 by supplying the data driving control signals DCS to the data driving circuit 130. The timing controller 140 can control the driving operation and driving timing of the gate driving circuit 120 by supplying the gate driving control signals GCS to the gate driving circuit 120.

The data driving circuit 130 can include one or more source driving integrated circuits SDIC. Each source driver integrated circuit SDIC can include a shift register, a latch circuit, a digital to analog converter, an output buffer, and the like. However, aspects of the present disclosure are not limited thereto. In one or more aspects, each source driver integrated circuit SDIC can further include an analog-to-digital converter (ADC).

In one or more aspects, each source driver integrated circuit SDIC can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

The gate driving circuit 120 can supply a gate signal of a turn-on level voltage, a gate signal of a turn-off level voltage, or a gate signal with a turn-on level and a turn-off level according to the control of the timing controller 140. The gate driving circuit 120 can sequentially drive a plurality of gate lines GL by sequentially supplying gate signals of the turn-on level voltage to the plurality of gate lines GL.

The gate driving circuit 120 can include one or more gate driving integrated circuits GDIC.

In one or more aspects, the gate driving circuit 120 can be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. However, aspects of the present disclosure are not limited thereto. In one or more aspects, the gate driving circuit 120 included in the display device 100 can be disposed in the bezel area BA of the display panel 110 by a gate-in-panel (GIP) technique. The gate driving circuit 120 can be disposed on a substrate, or connected to the substrate. In an example where the gate driving circuit 120 is implemented in the display device 100 by the gate-in-panel (GIP) technique, the gate driving circuit 120 can be disposed in the bezel area BA of the substrate. For example, when the GIP-type gate driving circuit 120 is used, the GIP-type gate driving circuit 120 can be disposed in, and/or electrically connected to, but not limited to, only one side or edge (e.g., a left portion or a right portion) of the display panel 110. In one or more aspects, the gate driving circuit 120 can be connected to the substrate when the gate driving circuit 130 is implemented by the chip-on-glass (COG) technique, the chip-on-film (COF) technique, or the like.

In one or more aspects, at least one of the data driving circuit 130 and the gate driving circuit 120 can be disposed in the display area DA. For example, at least one of the data driving circuit 130 and the gate driving circuit 120 can be disposed not to overlap with subpixels SP, or be disposed to overlap with one or more, or all, of the subpixels SP.

The data driving circuit 130 can be located in, and/or electrically connected to, but not limited to, only one side or edge (e.g., an upper portion or a lower portion) of the display panel 110. In one or more aspects, the data driving circuit 130 can be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The gate driving circuit 120 can be located in, and/or electrically connected to, but not limited to, only one side or edge (e.g., a left portion or a right portion) of the display panel 110. In one or more aspects, the gate driving circuit 120 can be disposed in, and/or electrically connected to, but not limited to, two sides or edges (e.g., a left portion and a right portion) of the display panel 110 or at least two of four sides or edges (e.g., the left portion, the right portion, an upper portion, and a lower portion) of the display panel 110 according to driving schemes, panel design schemes, or the like.

The timing controller 140 can be implemented in a separate component from the data driving circuit 130, or integrated with the data driving circuit 130, so that the timing controller 140 and the data driving circuit 130 can be implemented in a single integrated circuit. The timing controller 140 can be a controller used in the typical display technology or a control apparatus/device capable of additionally performing other control functionalities in addition to the typical function of the timing controller. In one or more embodiments, the timing controller 140 can be one or more other control circuits different from the timing controller, or a circuit or component in the control apparatus/device. The timing controller 140 can be implemented with various circuits or electronic components such as an integrated circuit (IC), a field programmable gate array (FPGA), an application specific integrated circuit (ASIC), a processor, and/or the like.

The timing controller 140 can be mounted on a printed circuit board, a flexible printed circuit, or the like, and can be electrically connected to the data driving circuit 130 and the gate driving circuit 120 through the printed circuit board, the flexible printed circuit, and/or the like. The timing controller 140 can transmit signals to, and receive signals from, the data driving circuit 130 via one or more predetermined interfaces. For example, such interfaces can include a low voltage differential signaling (LVDS) interface, an embedded clock point-point interface (EPI), a serial peripheral interface (SPI), and the like. However, aspects of the present disclosure are not limited thereto.

In one or more aspects, the display device 100 can be a self-emission display device in which light is emitted from the display panel 110 itself, or the like. In an example where the display device 100 is a self-emission display device, each of the plurality of subpixels SP included in the display device 100 can include a light emitting element such as an organic light emitting diode, an inorganic light emitting diode, a quantum dot light emitting diode, a micro light emitting diode, a mini light emitting diode, or the like. In one or more aspects, the display device 100 can be an organic light emitting display device in which the light emitting element is implemented using an organic light emitting diode (OLED). In one or more aspects, the display device 100 can be an inorganic light emitting display device in which the light emitting element is implemented using an inorganic material-based light emitting diode. In one or more aspects, the display device 100 can be a quantum dot display device in which the light emitting element is implemented using quantum dots, which are self-emission semiconductor crystals.

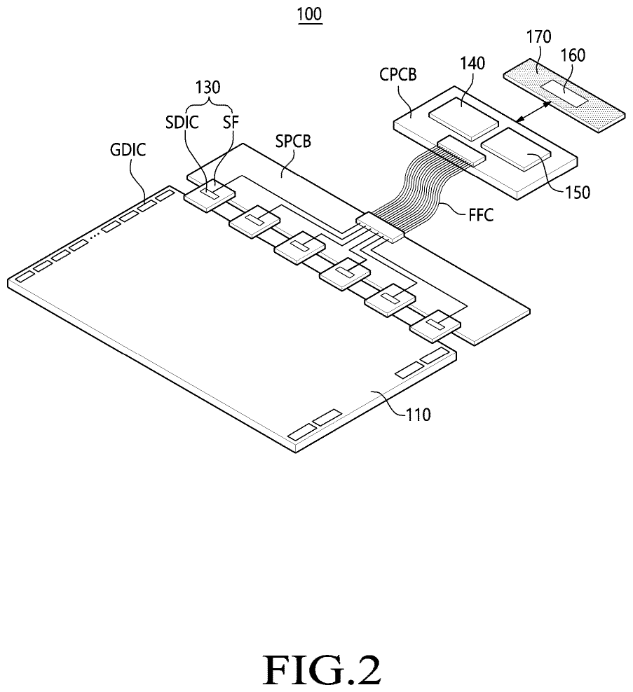

FIG. 2 illustrates an example system of the display device 100 according to aspects of the present disclosure.

Referring to FIG. 2, in one or more example embodiments, the data driving circuit 130 and the gate driving circuit 120 included in the display device 100 can be implemented by the chip-on-film (COF) technique and the gate-in-panel (GIP) technique, respectively, among various techniques such as the tape-automated-bonding (TAB) technique, the chip-on-glass (COG) technique, the chip-on-film (COF) technique, and the like.

In an example where the gate driving circuit 120 is implemented by the GIP technique, a plurality of gate driving integrated circuits GDIC included in the gate driving circuit 120 can be disposed directly in the non-display area NDA of the display panel 110. In this example, the gate driving integrated circuits GDIC can receive various types of signals (e.g., clock signals, gate high signals, gate low signals, and the like) needed for generating scan signals through gate driving-related signal lines disposed in the non-display area NDA.

In one or more aspects, one or more source driving integrated circuits SDIC included in the data driving circuit 130 can be mounted on one or more respective source films SF, and one side of each source film SF can be electrically connected to the display panel 110. In one or more aspects, lines for electrically connecting the one or more source driving integrated circuits SDIC and the display panel 110 can be respectively disposed in upper portions of the one or more source films SF.

The display device 100 can include at least one source printed circuit board SPCB for circuital connections between the one or more source driving integrated circuits SDIC and other units or devices, and a control printed circuit board CPCB for mounting control components and several types of electrical units or devices.

In one or more aspects, one side of a source film SF on which a source driving integrated circuit SDIC is mounted can be connected to the at least one source printed circuit board SPCB. For example, one side of the source film SF on which the source driving integrated circuit SDIC is mounted can be electrically connected to the at least one source printed circuit board SPCB, and the other side thereof can be electrically connected to the display panel 110.

The timing controller 140 and the power management circuit 150 can be mounted on the control printed circuit board CPCB. The timing controller 140 can control operations of the data driving circuit 130 and the gate driving circuit 120. The power management circuit 150 can supply various levels of voltages or currents to the display panel 110, the gate driving circuit 120, the data driving circuit 130, and the like, or control various levels of voltages or currents to be supplied.

The at least on source printed circuit board SPCB and the control printed circuit board CPCB can be electrically connected to each other through at least one connector, such as a flexible printed circuit FPC, a flexible flat cable FFC, and/or the like. In one or more aspects, the at least one source printed circuit board SPCB and the control printed circuit board CPCB can be integrated into one printed circuit board.

The display device 100 can further include a set board 170 electrically connected to the control printed circuit board CPCB. The set board 170 can be referred to as a power board. A main power management circuit 160 configured to manage the entire power of the display device 100 can be mounted on the set board 170. The main power management circuit 160 can interoperate with the power management circuit 150.

In the example where the display device 100 includes the power management circuit 150, the set board 170, the control printed circuit board CPCB, and the like as described above, one or more driving voltages generated by the set board 170 can be transmitted to the power management circuit 150 of the control printed circuit board CPCB. The power management circuit 150 can transmit one or more driving voltages needed for display driving or characteristic value sensing to the source printed circuit board SPCB through the flexible printed circuit FPC or the flexible flat cable FFC. One or more driving voltages transmitted to the source driver integrated circuit SPCB can be supplied to the display panel 110 through one or more source driver integrated circuits SDIC, and used to enable one or more specific subpixels SP to emit light or sense one or more subpixels SP.

In one or more aspects, each subpixel SP included in the display panel 110 of the display device 100 can include circuit elements, such as a light emitting element (e.g., an organic light emitting diode OLED), a driving transistor for driving the light emitting element, and the like.

Types of circuit elements and the number of the circuit elements included in each subpixel SP can be different depending on types of the panel (e.g., an LCD panel, an OLED panel, etc.), provided functions, design schemes/features, or the like.

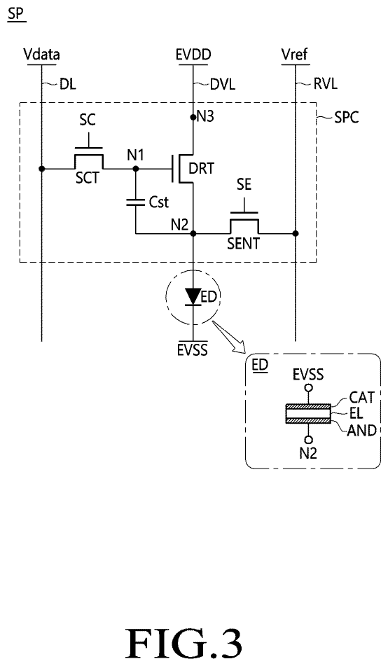

FIG. 3 illustrates an example equivalent circuit of each of subpixels included in the display panel 110 according to aspects of the present disclosure.

Referring to FIG. 3, in one or more example embodiments, each of a plurality of subpixels SP included in the touch display panel 110 can include a light emitting element ED and a subpixel circuit SPC for driving the corresponding light emitting element ED.

The subpixel circuit SPC of each subpixel can include a driving transistor DRT, a scan transistor SCT, a sensing transistor SENT, and a storage capacitor Cst. As shown in FIG. 3, as the subpixel circuit SPC of each subpixel is configured with three transistors (3T: DRT, SCT and SENT) and one capacitor (1C: Cst), this structure of subpixel circuit SPC can be referred to as a “3T1C structure”.

The light emitting element ED can include an anode electrode AND and a cathode electrode CAT, and include an emission layer EL located between the anode electrode AND and the cathode electrode CAT.

One of the anode electrode AND and the cathode electrode CAT can be a pixel electrode connected to a transistor such as the driving transistor DRT and the like, and the other can be a common electrode to which a common voltage is applied. The pixel electrode can be an electrode disposed in each subpixel SP, and the common electrode can be an electrode commonly disposed in all or two or more of the plurality of subpixels SP. For example, the common voltage can be a high voltage EVDD, which is a high level common voltage, or be a low voltage EVSS, which is a low level common voltage. The high voltage EVDD can be also referred to as a driving voltage, and the low voltage EVSS can be also referred to as a base voltage.

The anode electrode AND can be a pixel electrode connected to a transistor such as the driving transistor DRT and the like, and the cathode electrode CAT can be a common electrode to which the low voltage EVSS is applied.

For example, the light emitting element ED can be an organic light emitting diode (OLED), a light emitting diode (LED) based on an inorganic material, a quantum dot light emitting element, a micro light emitting diode, a mini light emitting diode, or the like.

The driving transistor DRT can be a transistor for driving the light emitting element ED, and can include a first node N1, a second node N2, and a third node N3.

The first node N1 of the driving transistor DRT can be the gate node of the driving transistor DRT, and can be electrically connected to the source node or drain node of the scan transistor SCT. The second node N2 of the driving transistor DRT can be the source node or drain node of the driving transistor DRT, and be electrically connected to the source node or drain node of the sensing transistor SENT and the anode electrode AND of the light emitting element ED. The third node N3 of the driving transistor DRT can be electrically connected to a driving voltage line DVL (which can be referred to as a high voltage line DVL) for delivering a high voltage EVDD.

The scan transistor SCT can be controlled by a scan signal SC, which is a type of gate signal, and can be connected between the first node N1 of the driving transistor DRT and a data line DL. For example, the scan transistor SCT can be turned on or turned off depending on a scan signal SC carried through a scan signal line SCL, which is a type of gate line GL, and can control an electrical connection between the data line DL and the first node N1 of the driving transistor DRT.

The scan transistor SCT can be turned on by a scan signal SC having a turn-on level voltage, and thereby, transfer a data voltage Vdata carried through the data line DL to the first node N1 of the driving transistor DRT.

For example, when the scan transistor SCT is an N-type transistor, the turn-on level voltage of the scan signal SC can be a high level voltage. In another example, when the scan transistor SCT is a P-type transistor, the turn-on level voltage of the scan signal SC can be a low level voltage. Hereinafter, for simplicity, discussions are provided based on the example where the scan transistor SCT is an N-type transistor. Accordingly, in discussions that follow, the turn-on level voltage of the scan signal SC can be a high level voltage.

The sensing transistor SENT can be controlled by a sensing signal SE, which is a type of gate signal, and can be connected between the second node N2 of the driving transistor DRT and a reference voltage line RVL. For example, the sensing transistor SENT can be turned on or turned off depending on a sensing signal SE carried through a sensing signal line SENL, which is another type of gate line GL, and can control an electrical connection between the second node N2 of the driving transistor DRT and the reference voltage line RVL.

The sensing transistor SENT can be turned on by a sensing signal SE having a turn-on level voltage, and thereby, transfer a reference voltage Vref carried through the reference voltage line RVL to the second node N2 of the driving transistor DRT. The sensing signal SE can be a second scan signal that is different from the scan signal SC.

The sensing transistor SENT can be turned on by a sensing signal SE having the turn-on level voltage, and thereby, can transfer a voltage at the second node N2 of the driving transistor DRT to the reference voltage line RVL.

For example, when the sensing transistor SENT is an N-type transistor, the turn-on level voltage of the sensing signal SE can be a high level voltage. In another example, when the sensing transistor SENT is a P-type transistor, the turn-on level voltage of the sensing signal SE can be a low level voltage. Hereinafter, for simplicity, discussions are provided based on the example where the sensing transistor SENT is an N-type transistor. Accordingly, in discussions that follow, the turn-on level voltage of the sensing transistor SENT can be a high level voltage.

For example, the function of the sensing transistor SENT configured to transfer the voltage of the second node N2 of the driving transistor DRT to the reference voltage line RVL can be used for sensing one or more characteristic values of a corresponding subpixel SP. In this implementation, the voltage transferred to the reference voltage line RVL can be a voltage to determine or calculate one or more characteristic values of the subpixel SP or a voltage in which one or more characteristic values of the subpixel SP are contained or reflected.

Herein, one or more characteristic values of a subpixel SP can be one or more characteristic values of a driving transistor DRT or a light emitting element ED. For example, one or more characteristic values of the driving transistor DRT can include a threshold voltage and/or mobility of the driving transistor DRT. For example, one or more characteristic values of the light emitting element ED can include a threshold voltage of the light emitting element ED.

The storage capacitor Cst can be connected between the first node N1 and the second node N2 of the driving transistor DRT. The storage capacitor Cst can store an amount of electric charge corresponding to a voltage difference between both terminals and maintain the voltage difference between both terminals for a preset frame time. Accordingly, a corresponding subpixel SP can emit light for a preset frame time.

Each of the driving transistor DRT, the scanning transistor SCT, and the sensing transistor SENT can be an N-type transistor or a P-type transistor. Herein, for convenience of description, discussions are provided based on an example where each of the driving transistor DRT, the scan transistor SCT, and the sensing transistor SENT is an N-type transistor.

The storage capacitor Cst can be an external capacitor intentionally designed to be located outside of the driving transistor DRT, other than an internal capacitor, such as a parasitic capacitor (e.g., a Cgs or a Cgd), that can be formed between the gate node and the source node (or the drain node) of the driving transistor DRT.

It should be noted that FIG. 3 illustrates just one example equivalent circuit of a subpixel SP, but aspects of the present disclosure are not limited thereto. For example, the subpixel SP can be modified in various structures by further including one or more transistors or one or more capacitors according to design requirements.

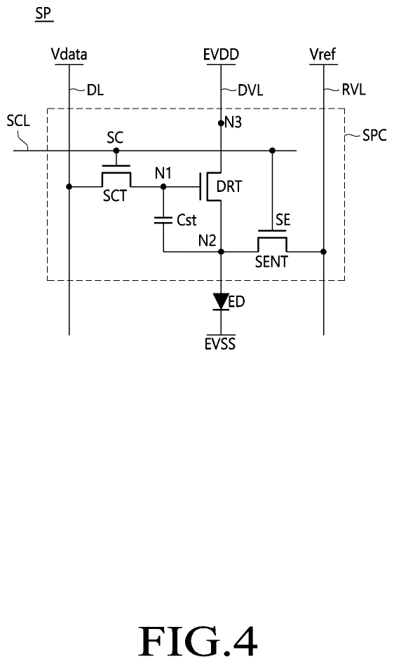

FIG. 4 illustrates an example equivalent circuit of a subpixel SP having a one-gate driven structure in the display panel 110 according to aspects of the present disclosure.

While FIG. 3 illustrates an example equivalent circuit of a subpixel SP having a two-gate driven structure, FIG. 4 illustrates an example equivalent circuit of a subpixel SP having a one-gate driven structure.

Referring to FIG. 4, in an example where a subpixel SP has a one-gate driven structure, the subpixel SP can be connected to a scan signal line SCL as one gate line GL.

In a subpixel circuit SPC of a subpixel SP having the one-gate driven structure, the gate node of a scan transistor SCT and the gate node of a sensing transistor SEN can be connected together to one scan signal line SCL. In this configuration, the scan transistor SCT and the sensing transistor SENT can operate together.

In the subpixel circuit SPC of a subpixel SP having the one-gate driven structure, both the gate node of the scan transistor SCT and the gate node of the sensing transistor SEN can be provided with a same scan signal SC together through the one scan signal line SCL.

In the subpixel circuit SPC of a subpixel SP having the one-gate driven structure, the scan signal SC supplied to the gate node of the sensing transistor SENT can serve as a sensing signal SE.

In an example where a subpixel SP has the one-gate driven structure, on and/or off timings of a scan transistor SCT and on and/or off timings of a sensing transistor SENT in the subpixel SP can be the same.

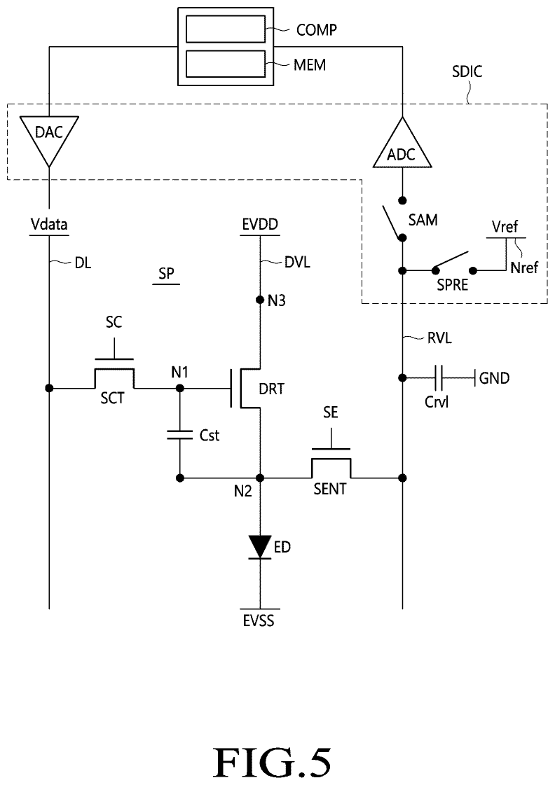

FIG. 5 illustrates an example compensation circuit for a subpixel SP included in the display device 100 according to aspects of the present disclosure. It should be noted that the subpixel SP of FIG. 5 can represent the subpixel SP in FIG. 3.

Referring to FIG. 5, in one or more example embodiments, the compensation circuit included in the display device 100 can be a circuit configured to perform sensing operation for one or more characteristic values of one or more circuit elements in a corresponding subpixel SP and an associated compensation process. For example, the circuit elements can include light emitting elements ED, driving transistors DRT, and the like.

The compensation circuit can include a sensing reference switch SPRE, a sampling switch SAM, an analog-to-digital converter ADC, a compensator COMP, a memory MEM, and the like. In one or more aspects, the compensation circuit can further include a subpixel SP.

The sensing reference switch SPRE can control a connection between a reference voltage line RVL and a reference voltage supply node Nref. A reference voltage Vref supplied by a power supply can be supplied to the reference voltage supply node Nref, and the reference voltage Vref supplied to the reference voltage supply node Nref can be applied to the reference voltage line RVL via the sensing reference switch SPRE.

The sampling switch SAM can control a connection between the analog-to-digital converter ADC and the reference voltage line RVL. When the analog-to-digital converter ADC is connected to the reference voltage line RVL by the sampling switch SAM, the analog-to-digital converter ADC can convert a voltage (analog voltage) of the connected reference voltage line RVL into a sensing value in the form of digital value.

As the subpixel SP is driven, a line capacitor Crvl can be formed between the reference voltage line RLV and the ground GND. The voltage of the reference voltage line RVL can correspond to an amount of electric charges stored across the line capacitor Crvl.

The analog-to-digital converter ADC can provide sensing data containing the sensing value to the compensator COMP.

The compensator COMP can determine at least one corresponding characteristic value of at least one circuit element (e.g., the light emitting element ED, the driving transistor DRT, and/or the like) included in the subpixel SP based on the sensing data from the analog-to-digital converter ADC. Thereafter, the compensator COMP can determine a compensation value to reduce or eliminate a difference in characteristic values between circuit elements based on the at least one characteristic value, and store the compensation value in the memory MEM.

For example, the compensation value can be information determined to reduce or eliminate a difference in characteristic values between light emitting elements ED or a difference in characteristic values between driving transistors DRT, and include an offset and/or a gain for modifying data.

The timing controller 140 can modify image data using the compensation value stored in the memory MEM, and supply the modified image data to the data driving circuit 130.

The data driving circuit 130 can convert the changed image data into a data voltage Vdata in the form of analog voltage by using a digital-to-analog converter DAC, and output the data voltage Vdata. In this manner, the compensation process can be executed.

In one or more aspects, the analog-to-digital converter ADC, the sensing reference switch SPRE, and the sampling switch SAM can be included in a source driver integrated circuit SDIC. In this implementation, the source driver integrated circuit SDIC can be an integrated circuit serving as the data driving circuit 120 or a part of the data driving circuit 120, and include the digital-to-analog converter DAC.

In one or more aspects, the compensator COMP can be included in the timing controller 140.

As described above, the display device 100 can perform the compensation process to reduce a difference in characteristic values between the driving transistors DRT. Further, to perform the compensation process, the display device 100 can perform sensing driving to acquire information on a difference in characteristic values between the driving transistors DRT.

In one or more aspects, the display device 100 can perform sensing driving in two sensing modes (a first sensing mode and a second sensing mode).

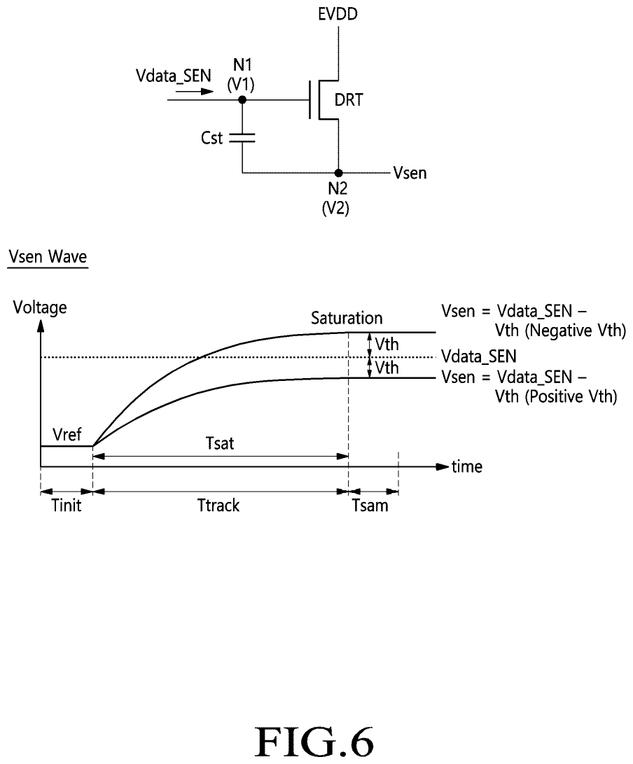

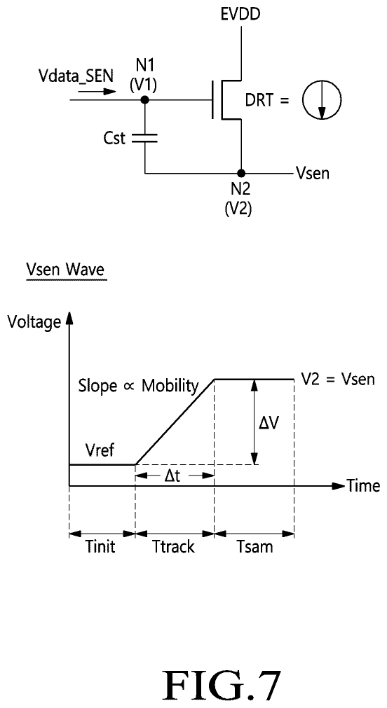

FIG. 6 illustrates an example first sensing mode used in the display device 100 according to aspects of the present disclosure. FIG. 7 illustrates an example second sensing mode used in the display device 100 according to aspects of the present disclosure.

Referring to FIG. 6, the “first sensing mode” can be a sensing mode for sensing a threshold voltage, which requires a relatively long sensing time, among characteristic values (e.g., the threshold voltage and mobility) of a driving transistor DRT. The first sensing mode can also be referred to as a “slow sensing mode” or a “threshold voltage sensing mode.”

Referring to FIG. 7, the “second sensing mode” can be a sensing mode for sensing mobility, which requires a relatively short sensing time, among characteristic values (e.g., the threshold voltage and mobility) of a driving transistor DRT. The second sensing mode can also be referred to as a “fast sensing mode” or a “mobility sensing mode.”

Hereinafter, sensing driving in the first sensing mode and sensing driving in the second sensing mode will be described with reference to the compensation circuit of FIG. 5, as well as FIGS. 6 and 7.

First, sensing driving in the first sensing mode will be described with reference to FIG. 6.

Referring FIG. 6, a sensing driving period of the first sensing mode can include an initialization sub-period Tinit, a tracking sub-period Ttrack, and a sampling sub-period Tsam.

The initialization sub-period Tinit of the sensing driving period in the first sensing mode can be a period for initializing a first node N1 and a second node N2 of a driving transistor DRT.

During the initialization sub-period Tinit, a voltage V1 of the first node N1 of the driving transistor DRT can be initialized to a sensing driving data voltage Vdata_SEN, and a voltage V2 of the second node N2 of the driving transistor DRT can be initialized to a sensing driving reference voltage Vref.

During the initialization sub-period Tinit, a scan transistor SCT and a sensing transistor SENT can be turned on, and a sensing reference switch SPRE can be turned on.

The tracking sub-period Ttrack of the sensing driving period in the first sensing mode can be a period for tracking a voltage V2 of the second node N2 of the driving transistor DRT containing or reflecting a threshold voltage Vth of the driving transistor DRT or a shift ΔVth in the threshold voltage Vth.

During the tracking sub-period Track, the sensing reference switch SPIRE can be turned off or the sensing transistor SENT can be turned off.

Accordingly, during the tracking sub-period Ttrack, while the first node N1 of the driving transistor DRT can be in a constant voltage state with the sensing driving data voltage Vdata_SEN, the second node N2 of the driving transistor DRT can be electrically floating. Accordingly, during the tracking sub-period Ttrack, the voltage V2 of the second node N2 of the driving transistor DRT can vary.

During the tracking sub-period Ttrack, the voltage V2 of the second node N2 of the driving transistor DRT can increase until the voltage V2 of the second node N2 of the driving transistor DRT contains or reflects a threshold voltage Vth of the driving transistor DRT (i.e., until the voltage V2 of the second node N2 of the driving transistor DRT reaches a saturation point at which the threshold voltage Vth of the driving transistor DRT (or a shift ΔVth in the threshold voltage Vth) is contained or reflected in the voltage V2 of the second node N2 of the driving transistor DRT).

During the initialization sub-period Tinit, a voltage difference between the first node N1 and the second node N2 of the driving transistor DRT, which have been initialized, can be greater than or equal to the threshold voltage Vth of the driving transistor DRT. Accordingly, when the tracking sub-period Ttrack is initiated, the driving transistor DRT can be in a turn-on state and allow current to flow. Thereby, when the tracking sub-period Ttrack is initiated, the voltage V2 of the second node N2 of the driving transistor DRT can increase.

During the tracking sub-period Ttrack, the voltage V2 of the second node N2 of the driving transistor DRT cannot continuously increase.

As the latter part of the tracking sub-period Ttrack progresses, an increasing width of the voltage V2 of the second node N2 of the driving transistor DRT can be reduced, and the voltage V2 of the second node N2 of the driving transistor DRT can be eventually saturated.

A saturated voltage V2 of the second node N2 of the driving transistor DRT can correspond to a difference (Vdata_SEN−Vth) between the sensing driving data voltage Vdata_SEN and the threshold voltage Vth or a difference (Vdata_SEN−ΔVth) between the sensing driving data voltage Vdata_SEN and a shift in the threshold voltage ΔVth. The threshold voltage Vth can be a negative threshold voltage (−Vth) or a positive threshold voltage (+Vth).

When voltage V2 of the second node N2 of the driving transistor DRT is saturated, the sampling sub-period Tsam can proceed.

The sampling sub-period Tsam of the sensing driving period in the first sensing mode can be a period for measuring a voltage (i.e., Vdata_SEN-Vth, Vdata_SEN-ΔVth) reflecting or reflecting the threshold voltage Vth of the driving transistor DRT or a shift in the threshold voltage Vth.

During the sampling sub-period Tsam of the sensing driving period in the first sensing mode, a voltage of the reference voltage line RVL can be sensed by the analog-to-digital converter ADC. The voltage of the reference voltage line RVL can correspond to the voltage of the second node N2 of the driving transistor DRT, and correspond to a charging voltage of a line capacitor Crvl formed on the reference voltage line RVL.

During the sampling sub-period Tsam, a voltage Vsen sensed by the analog-to-digital converter ADC can be the voltage (Vdata_SEN−Vth) resulting from subtracting the threshold voltage Vth from the sensing driving data voltage Vdata_SEN or the voltage (Vdata_SEN−ΔVth) resulting from subtracting the threshold voltage shift ΔVth from the sensing driving data voltage Vdata_SEN. The threshold voltage Vth can be a positive threshold voltage or a negative threshold voltage.

During the tracking sub-period Ttrack of the sensing driving period in the first sensing mode, a saturation time Tsat required for the voltage V2 of the second node N2 of the driving transistor DRT to reach saturation after increasing can be, as a time period of the tracking sub-period Ttrack of the sensing driving period in the first sensing mode, a time taken until the threshold voltage (Vth) of the driving transistor DRT or the threshold voltage shift (ΔVth) is reflected or contained on the voltage (V2=Vdata_SEN−Vth, or V2=Vdata_SEN−ΔVth) of the second node N2 of the driving transistor DRT.

This saturation time Tsat can occupy most of the entire time period of the sensing driving period in the first sensing mode. Thus, in the case of the first sensing mode, it can take quite a long time (saturation time Tsat) for the voltage V2 of the second node N2 of a driving transistor DRT to reach saturation after increasing.

As described above, the sensing driving method for sensing the threshold voltage of a driving transistor DRT (i.e., the first sensing mode) can be sometimes referred to as a slow mode since a long saturation time Tsat is required until the voltage of the second node N2 of the driving transistor DRT contains or reflects the threshold voltage of the driving transistor DRT.

Next, sensing driving in the second sensing mode will be described with reference to FIG. 7.

Referring to FIG. 7, a sensing driving period of the second sensing mode can include an initialization sub-period Tinit, a tracking sub-period Ttrack, and a sampling sub-period Tsam.

The initialization sub-period Tinit of the sensing driving period in the second sensing mode can be a period for initializing a first node N1 and a second node N2 of a driving transistor DRT.

During the initialization sub-period Tinit, a scan transistor SCT and a sensing transistor SENT can be turned on, and a sensing reference switch SPRE can be turned on.

During the initialization sub-period Tinit, a voltage V1 of the first node N1 of the driving transistor DRT can be initialized to a sensing driving data voltage Vdata_SEN, and a voltage V2 of the second node N2 of the driving transistor DRT can be initialized to a sensing driving reference voltage Vref.

The tracking sub-period Ttrack of the sensing driving period in the second sensing mode can be a period for changing the voltage V2 of the second node N2 of the driving transistor DRT for a preset tracking time Δt until the voltage V2 of the second node N2 of the driving transistor DRT reaches a voltage containing or reflecting mobility of the driving transistor DRT or a shift in the mobility.

During the tracking sub-period Ttrack, the preset tracking time Δt can be set to a relatively short time. Therefore, it can be difficult for the voltage V2 of the second node N2 of the driving transistor DRT to contain or reflect the threshold voltage Vth of the driving transistor DRT for a short tracking time Δt. To address this issue, voltage V2 of the second node N2 of the driving transistor DRT can be changed enough to determine the mobility of the driving transistor DRT for such a short tracking time Δt.

Accordingly, the second sensing mode can be a sensing driving method for sensing the mobility of a driving transistor DRT.

During the tracking sub-period Ttrack, the sensing reference switch SPRE can be turned off or the sensing transistor SENT can be turned off, and therefore, the second node N2 of the driving transistor DRT can be electrically floating.

During the tracking sub-period Ttrack, the scan transistor SCT can be turned off by a scan signal SC of a turn-off level voltage, and therefore, the first node N1 of the driving transistor DRT can be also electrically floating.

During the initialization sub-period Tinit, a voltage difference between the first node N1 and the second node N2 of the driving transistor DRT, which have been initialized, can be greater than or equal to the threshold voltage Vth of the driving transistor DRT. Accordingly, when the tracking sub-period Ttrack is initiated, the driving transistor DRT can be in a turn-on state and allow current to flow.

The voltage difference between the first node N1 and the second node N2 of the driving transistor DRT can be denoted as Vgs when the first node N1 and the second node N2 of the driving transistor DRT are the gate node and the source node, respectively.

Accordingly, during the tracking sub-period Ttrack, the voltage V2 of the second node N2 of the driving transistor DRT can vary. In this situation, voltage V1 of the first node N1 of the driving transistor DRT can also increase.

During the tracking sub-period Ttrack, an increasing rate of voltage V2 of the second node N2 of the driving transistor DRT can vary depending on the current capability (i.e., mobility) of the driving transistor DRT. As the driving transistor DRT has greater current capability (mobility), the voltage V2 of the second node N2 of the driving transistor DRT can increase more steeply.

After the tracking sub-period Ttrack progresses for the preset tracking time Δt, for example, after the voltage V2 of the second node N2 of the driving transistor DRT increases for the preset tracking time Δt, the sampling sub-period Tsam can proceed

During the tracking sub-period Ttrack, an increasing rate of the voltage V2 of the second node N2 of the driving transistor DRT can corresponds to an amount of voltage variance ΔV in the second node N2 of the driving transistor DRT during the preset tracking time Δt. The amount of voltage variance ΔV in the second node N2 of the driving transistor DRT can correspond to an amount of voltage variance in the reference voltage line RVL.

After the tracking sub-period Ttrack progresses for the preset tracking time Δt, the sampling sub-period Tsam can proceed. During the sampling sub-period Tsam, the sampling switch SAM can be turned on, and the reference voltage line RVL and the analog-to-digital converter ADC can be electrically connected.

The analog-to-digital converter ADC can sense a voltage of the reference voltage line RVL. The voltage Vsen sensed by the analog-to-digital converter ADC can be a voltage (Vref+ΔV) increased from the reference voltage Vref by the amount of voltage variance ΔV for the preset tracking time Δt.

The voltage Vsen sensed by the analog-to-digital converter ADC can be, as the voltage of the reference voltage line RVL, the voltage of the second node N2 electrically connected to the reference voltage line RVL through the sensing transistor SENT.

In the sampling sub-period Tsam of the sensing driving period in the second sensing mode, the voltage Vsen sensed by the analog-to-digital converter ADC can vary depending on the mobility of the driving transistor DRT. As the driving transistor DRT has higher mobility, the sensing voltage Vsen can increase. As the driving transistor DRT has lower mobility, the sensing voltage Vsen can decrease.

As described above, the sensing driving method for sensing the mobility of a driving transistor DRT (i.e., the second sensing mode) can be sometimes referred to as a fast mode since this method can be executed by changing the voltage of the second node N2 of the driving transistor DRT for such a short period of time Δt.

The compensator COMP can detect a threshold voltage Vth or a shift in the threshold voltage Vth of a driving transistor DRT of a corresponding subpixel SP based on sensing data corresponding to a voltage Vsen sensed through the first sensing mode, determine a threshold voltage compensation value for reducing or eliminating a difference in threshold voltages between driving transistors DRT, and store the acquired threshold voltage compensation value in the memory MEM.

Further, the compensator COMP can detect mobility or a shift in the mobility of a driving transistor DRT of a corresponding subpixel SP based on sensing data corresponding to a voltage Vsen sensed through the second sensing mode, determine a mobility compensation value for reducing or eliminating a difference in mobilities between driving transistors DRT, and store the acquired mobility compensation value in the memory MEM.

The timing controller 140 can modify data Data based on the threshold voltage compensation value Φ and mobility compensation value a stored in the memory MEM, and supply the modified data (Data′=α×Data+Φ) to the data driving circuit 130.

The data driving circuit 120 can convert the data (Data′=α×Data+Φ) supplied by the controller 140 into a data voltage Vdata, and supply the converted data voltage Vdata to the corresponding subpixel SP. The data voltage Vdata supplied to the corresponding subpixel SP can be a data voltage Vdata capable of reducing a difference in threshold voltages and a difference in mobilities.

As described above, since a long sensing time is required for threshold voltage sensing, and a short sensing time is sufficient for mobility sensing, therefore, the threshold voltage sensing can be performed in the first sensing mode corresponding to the slow sensing mode, and the mobility sensing can be performed in the second sensing mode corresponding to the fast sensing mode.

As discussed above, since a long time is required to sense the threshold voltage Vth of a driving transistor DRT included in a subpixel SP, the display panel 110 or the display device is needed to have a structure of effectively reducing the sensing time.

In this regard, a reference voltage line RVL can be disposed one by one for each column of subpixels SP, or can be disposed to share two or more subpixels SP disposed in each row for driving efficiency.

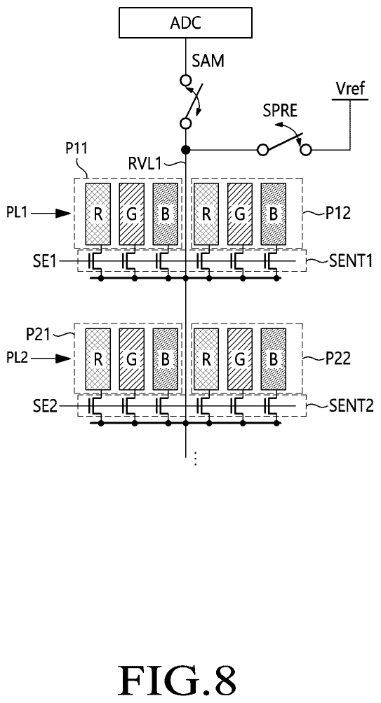

FIG. 8 illustrates an example reference voltage line sharing structure in the display panel 110 according to aspects of the present disclosure.

Referring to FIG. 8, in one or more example embodiments, two or more subpixels SP included in the display panel 110 can share a reference voltage line RVL for driving and sensing efficiency. In this configuration, a plurality of pixels sharing one reference voltage line can be referred to as a pixel group.

For example, in a configuration where a plurality of pixel lines each includes a plurality of pixels each including a plurality of subpixels and disposed in a row direction, and each of the plurality of pixel lines is disposed in a corresponding row in a column direction, a first pixel located in a first column and a second pixel located in a second column can share a first reference voltage line RVL1. In this example, a pixel group can include first and second pixels adjacent to each other in the row direction.

According to the foregoing configurations, the first reference voltage line RVL1 can be shared by respective first sensing transistors SENT1 included in a pixel P11 in a first row and a first column and a pixel P12 in the first row and a second column, among pixels included in a first pixel line PL1 disposed in the first row.

Further, the first reference voltage line RVL1 can be shared by respective second sensing transistors SENT2 included in a pixel P21 in a second row and the first column and a pixel P22 in the second row and the second column, among pixels included in a second pixel line PL2 disposed in the second row.

In an example where one pixel includes a red subpixel R, a green subpixel G, and a blue subpixel B, and two pixels shares one reference voltage line, as six subpixels in each row share one first reference voltage line RVL1, the first reference voltage line RVL1 can be connected to respective six sensing transistors included in the six subpixels.

For example, when gate lines included in the display panel 110 equal to 2,304 lines, one reference voltage line can be shared by 6×2,304 sensing transistors.

According to these configurations, as the number of subpixels (sensing transistors) sharing one reference voltage line increases, a load of the reference voltage line can increases, and a tracking sub-period Ttrack for sensing one or more characteristic values of each subpixel can become greater.

In another example, when gate lines included in the display panel 110 equal to 2,304 lines, and one reference voltage line is shared by four pixels (12 subpixels), a tracking sub-period Ttrack for sensing one or more characteristic values of one subpixel through the first sensing mode can be a length of about 130 ms. Therefore, a characteristic value sensing time for all subpixels included in the display panel 110 can be about 1 hour (130 ms×12 subpixels×2,304 lines=3,594 sec). In this example, four adjacent pixels can form one pixel group.

In one or more aspects, the display panel 110 or the display device 100 can be configured to have a structure capable of reducing a time of sensing characteristic values of driving transistors by reducing loads of reference voltage lines for sensing the characteristic values of the driving transistors.

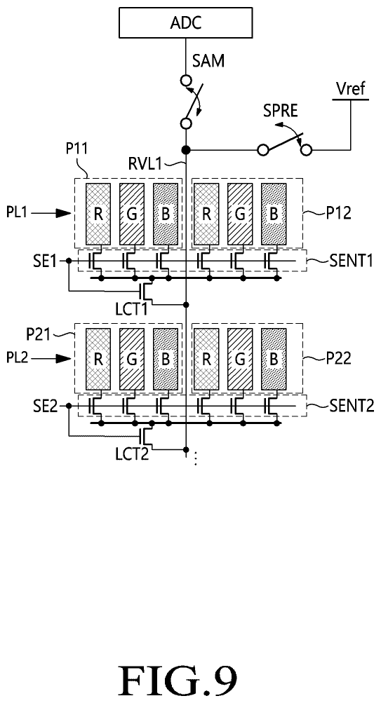

FIG. 9 illustrates an example structure of the display panel 110 according to aspects of the present disclosure.

Referring to FIG. 9, in one or more example embodiments, two or more subpixels SP included in the display panel 110 can share a reference voltage line RVL for driving and sensing efficiency.

For example, in a configuration where a plurality of pixel lines each includes a plurality of pixels each including a plurality of subpixels and disposed in a row direction, and each of the plurality of pixel lines is disposed in a corresponding row in a column direction, a first pixel located in a first column and a second pixel located in a second column can share a first reference voltage line RVL1. In this example, one pixel group sharing one reference voltage line can include two pixels.

In one or more aspects, a first reference voltage line RVL1 can be connected to sensing transistors included in each pixel through a load control transistor LCT.

For example, the first reference voltage line RVL1 can be connected to respective first sensing transistors SENT1 included in a pixel P11 in a first row and a first column and a pixel P12 in the first row and a second column, among pixels included in a first pixel line PL1 disposed in the first row through a first load control transistor LCT1.

For example, a first node (e.g., the gate node) of the first load control transistor LCT1 can be applied with a first sensing signal SE1 for controlling the first sensing transistors SENT1. A second node (e.g., the source node or drain node) of the first load control transistor LCT1 can be connected to the first reference voltage line RVL1. A third node (e.g., the drain node or source node) of the first load control transistor LCT1 can be connected to the source node or drain node of the first sensing transistors SENT1.

According to these configurations, the first load control transistor LCT1 can be turned on together with the first sensing transistors SENT1, and thereby, connect the first sensing transistors SENT1 to the first reference voltage line RVL1 during a period in which the first sensing transistors SENT1 are turned on.

Further, the first reference voltage line RVL1 can be connected to respective second sensing transistors SENT2 included in a pixel P21 in a second row and the first column and a pixel P22 in the second row and the second column, among pixels included in a second pixel line PL2 disposed in the second row through a second load control transistor LCT2.

For example, a first node (e.g., the gate node) of the second load control transistor LCT2 can be applied with a second sensing signal SE2 for controlling the second sensing transistors SENT2. A second node (e.g., the source node or drain node) of the second load control transistor LCT2 can be connected to the first reference voltage line RVL1. A third node (e.g., the drain node or source node) of the second load control transistor LCT2 can be connected to the source node or drain node of the second sensing transistors SENT2.

According to these configurations, the second load control transistor LCT2 can be turned on together with the second sensing transistors SENT2, and thereby, connect the second sensing transistors SENT2 to the first reference voltage line RVL1 during a period in which the second sensing transistors SENT2 are turned on.

In an example where one pixel includes a red subpixel R, a green subpixel G, and a blue subpixel B, and two pixels shares one reference voltage line, as six subpixels in each row share one first reference voltage line RVL1, the first reference voltage line RVL1 can be connected to respective six sensing transistors included in the six subpixels through one load control transistor.

In this example, since sensing signal lines of the display panel 110 are sequentially applied with sensing signals, a reference voltage line can be electrically connected only to a sensing transistor turned on by a corresponding sensing signal during a period in which the sensing signal is applied.

In this implementation, a load control transistor can be disposed for each pixel group sharing the reference voltage line. In one or more aspects, the load control transistor can be disposed for each pixel line, or can be disposed for each odd-numbered pixel line or each even-numbered pixel line. In one or more aspects, the load control transistor can be disposed only for one or more pixel lines among all pixel lines of the display panel 110.

In one or more aspects, the load control transistor can be the same N-type transistor as sensing transistors.

According to the foregoing configurations, the number of sensing transistors connected to one reference voltage line during a period in which a sensing signal is applied can be reduced, and thereby, a load of the reference voltage line can be reduced. Accordingly, a tracking sub-period Ttrack for sensing characteristic values of subpixels can be reduced, and thereby, a corresponding characteristic value sensing time can be reduced.

In one or more aspects, the number of pixel groups connected to one reference voltage line included in the display panel 110 can be different depending on design requirements.

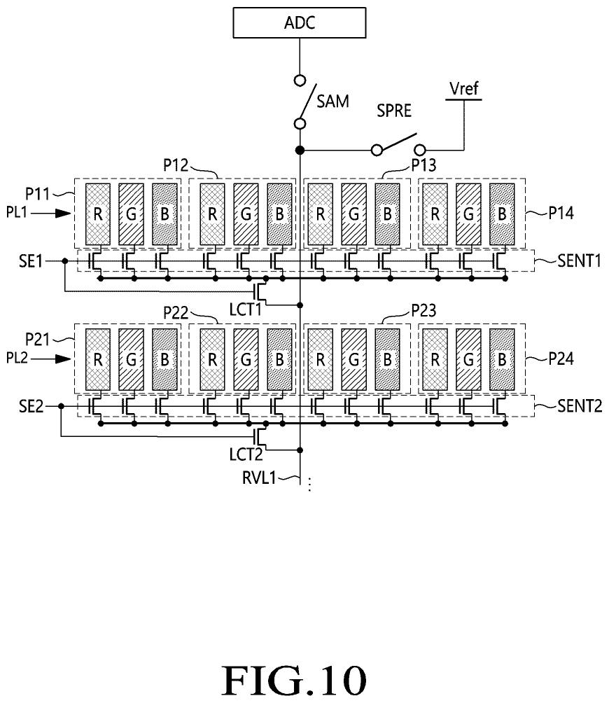

FIG. 10 illustrates another example structure of the display panel 100 according to aspects of the present disclosure.

Referring to FIG. 10, in one or more example embodiments, four or more subpixels SP included in the display panel 110 can share a reference voltage line RVL for driving and sensing efficiency. In this configuration, one pixel group sharing one reference voltage line can include four pixels.

For example, in a configuration where a plurality of pixel lines each includes a plurality of pixels each including a plurality of subpixels and disposed in a row direction, and each of the plurality of pixel lines is disposed in a corresponding row in a column direction, first to fourth pixels adjacent to each other in each pixel line can share a first reference voltage line RVL1.

In this example, the first reference voltage line RVL1 can be connected to sensing transistors included in each pixel line through a load control transistor LCT.

For example, the first reference voltage line RVL1 can be connected to respective first sensing transistors SENT1 included in a pixel P11 in a first row and a first column and a pixel P12 in the first row and a second column, a pixel P13 in the first row and a third column and a pixel P14 in the first row and a fourth column, among pixels included in a first pixel line PL1 disposed in the first row through a first load control transistor LCT1.

According to this example, the first load control transistor LCT1 can be turned on together with the first sensing transistors SENT1, and thereby, connect the first sensing transistors SENT1 to the first reference voltage line RVL1 during a period in which the first sensing transistors SENT1 are turned on.

Further, the first reference voltage line RVL1 can be connected to respective second sensing transistors SENT2 included in a pixel P21 in a second row and the first column, a pixel P22 in the second row and the second column, a pixel P23 in the second row and the third column, and a pixel P24 in the second row and the fourth column, among pixels included in a second pixel line PL2 disposed in the second row through a second load control transistor LCT2.

According to this example, the second load control transistor LCT2 can be turned on together with the second sensing transistors SENT2, and thereby, connect the second sensing transistors SENT2 to the first reference voltage line RVL1 during a period in which the second sensing transistors SENT2 are turned on.

In an example where one pixel includes a red subpixel R, a green subpixel G, and a blue subpixel B, and four pixels shares one reference voltage line, as twelve subpixels in each row share one first reference voltage line RVL1, the first reference voltage line RVL1 can be connected to respective twelve sensing transistors included in the twelve subpixels through one load control transistor.

In this example, since sensing signal lines of the display panel 110 are sequentially applied with sensing signals, a reference voltage line can be electrically connected only to a sensing transistor turned on by a corresponding sensing signal during a period in which the sensing signal is applied.

According to the foregoing configurations, the number of sensing transistors connected to one reference voltage line during a period in which a sensing signal is applied can be reduced, and thereby, the load of the reference voltage line can be reduced. Accordingly, a tracking sub-period Ttrack for sensing characteristic values of subpixels can be reduced, and thereby, a corresponding characteristic value sensing time can be reduced.

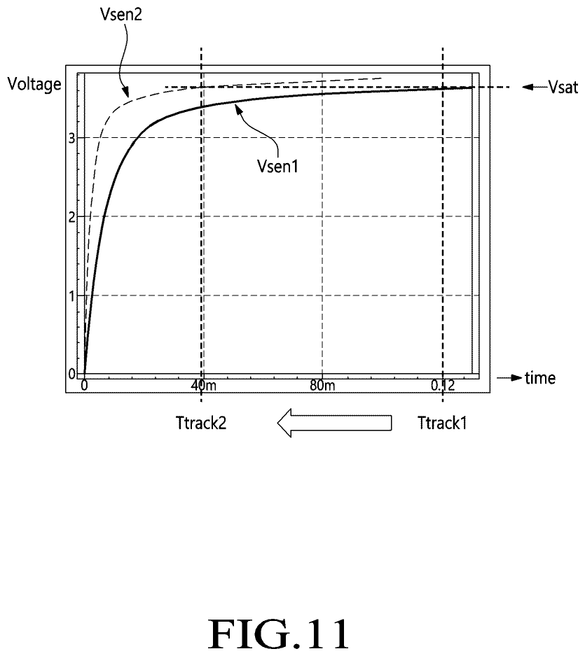

FIG. 11 is an experimental graph showing a difference between characteristic value sensing times in the display panel 110 according to aspects of the present disclosure.

Referring to FIG. 11, in one or more aspects, in the display panel 110, a reference voltage line can be electrically connected only to one or more sensing transistors turned on by a specific sensing signal during a period in which the sensing signal is applied.

Accordingly, the number of sensing transistors connected to one reference voltage line during a period in which a sensing signal is applied can be reduced, and thereby, a load of the reference voltage line can be reduced. As a result, a tracking sub-period Ttrack for sensing characteristic values of corresponding one or more subpixels can be reduced, and thereby, a corresponding characteristic value sensing time can be reduced.

For example, when gate lines of the display panel 110 equal to 2,304 lines and one reference voltage line is shared by four pixels (i.e., 12 subpixels), the number of sensing transistors connected to one reference voltage line in a period for sensing characteristic values of corresponding subpixels can be 27,648 (i.e., 12×2,304 lines=27,648).

In this example, a first tracking sub-period Ttrack1 to sense a first sensing voltage Vsen1 corresponding to the characteristic values of the subpixels through the first sensing mode can be a length of about 130 ms.

Therefore, a characteristic value sensing time for all of subpixels included in the display panel 110 can be about 1 hour (130 ms×12 subpixels×2,304 lines=3,594 sec).

In contrast, in the display panel 110 including load control transistors, the number of sensing transistors connected to one reference voltage line in a period for sensing characteristic values of subpixels by a load control transistor can be 12.

In this case, a slew rate of a sensing voltage detected through the reference voltage line can increase. As a result, a second tracking sub-period Ttrack2 can be reduced to a length of about 38.3 ms for sensing a first sensing voltage Vsen1 corresponding to the characteristic values of the subpixels through the first sensing mode.

Accordingly, a characteristic value sensing time for all of subpixels disposed in the display panel 110 including load control transistors can be about 17 minutes (38.3 ms×12 subpixels×2,304 lines=1.58 sec).

As discussed above, the display panel 110 can reduce the number of sensing transistors connected to one reference voltage line during a period in which a sensing signal is applied through a load control transistor, and reduce a load of the reference voltage line. Thereby, the display panel 110 can reduce a tracking sub-period Ttrack for sensing characteristic values of subpixels, and reduce a corresponding sensing time.

In one or more aspects, in the display device 100, the technology of sensing characteristic values of subpixels through a reference voltage line can be applied to subpixel circuits of various structures.

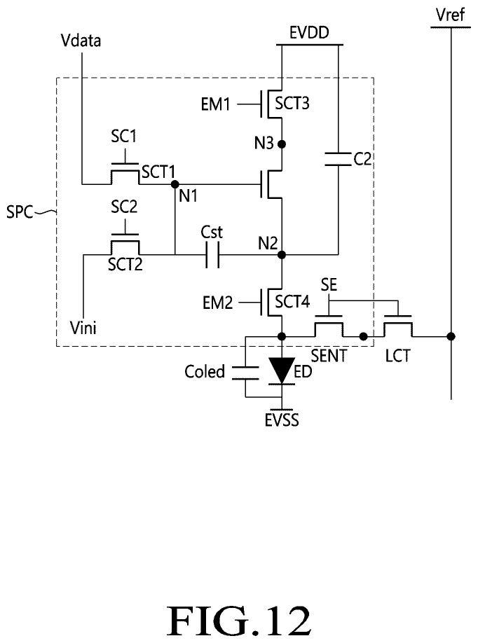

FIG. 12 illustrates an example subpixel structure in the display panel 110 according to aspects of the present disclosure.

Referring to FIG. 12, in one or more example embodiments, the display panel 110 can include a light emitting element ED, a subpixel circuit SPC, and a load control transistor LCT.

The subpixel circuit SPC can include a driving transistor DRT for supplying a current to the light emitting element ED, a plurality of scan transistors (SCT1, SCT2, SCT3, and SCT4) for switching current paths connected to the driving transistor DRT, and a plurality of capacitors (Cst, and C2) for storing source node voltages of the driving transistor DRT.

The driving transistor DRT and the plurality of scan transistors (SCT1, SCT2, SCT3, and SCT4) can be N-type transistors.

The light emitting element ED can emit light by a current flowing through a channel of the driving transistor DRT depending on a gate-source voltage Vgs of the driving transistor DRT that changes according to a data voltage Vdata.

The light emitting element ED can be implemented as an organic light emitting diode including an organic compound layer located between an anode electrode and a cathode electrode. The organic compound layer can include, but is not limited to, a hole injection layer, a hole transport layer, an emission layer, an electron transport layer, and an electron injection layer.

The anode electrode of the light emitting element ED can be connected to a second node N2 of the driving transistor DRT through a fourth scan transistor SCT4, and the cathode electrode of the light emitting element ED can be connected to a low voltage line to which a low voltage EVSS is applied.

The light emitting element ED can have a tandem structure in which a plurality of light emitting layers are stacked. The light emitting element ED of the tandem structure can improve luminance and lifetime of a corresponding subpixel.

The driving transistor DRT can supply current to the light emitting element ED depending on the gate-source voltage Vgs to drive the light emitting element ED. The driving transistor DRT can include a first node N1 connected to a first scan transistor SCT1 and a second scan transistor SCT2, a third node N3 connected to a third scan transistor SCT3, and the second node N2 connected to the fourth scan transistor SCT4.

The first node N1, the second node N2, and the third node N3 of the driving transistor DRT can be a gate node, a source node, and a drain node, respectively. It should be noted that the second node N2 and the third node N3 can be switched depending on types of the driving transistor DRT.

The first scan transistor SCT1 can be turned on by a turn-on voltage of a first scan signal SC1 and transfer a data voltage Vdata to the first node N1.

The first scan transistor SCT1 can include a gate node to which the first scan signal SC1 is applied, a drain node (or a source node) to which the data voltage Vdata is applied, and the source node (or the drain node) connected to the first node N1.

The second scan transistor SCT2 can be turned on by a turn-on voltage of a second scan signal SC2 and transfer an initialization voltage Vini to the first node N1. The second scan transistor SCT2 can include a gate node to which the second scan signal SC2 is applied, a drain node (or a source node) to which the initialization voltage Vini is applied, and the source node (or the drain node) connected to the first node N1.

The third scan transistor SCT3 can be turned on by a turn-on voltage of a first emission signal EM1 and transfer a high voltage EVDD to the third node N3. The third scan transistor SCT can include a gate node to which the first emission signal EM1 is applied, a source node (or a drain node) connected to the third node N3, and the drain node (or the source node) to which the high voltage EVDD is applied.

The fourth scan transistor SCT4 can be turned on by a turn-on voltage of a second emission signal EM2 and connect the second node N2 and the anode electrode of the light emitting element ED. The fourth scan transistor SCT4 can include a gate node to which the second emission signal EM2 is applied, a drain node (or a source node) connected to the second node N2, and the source node (or the drain node) connected to the anode electrode of the light emitting element ED.

The third scan transistor SCT3 and the fourth scan transistor SCT4 can be referred to as a first emission control transistor and a second emission control transistor.

A sensing transistor SENT can be turned on by a turn-on voltage of a sensing signal SE and supply a reference voltage Vref to the anode electrode of the light emitting element ED.

In this configuration, to reduce a load of a reference voltage line to which the reference voltage Vref is applied, a load control transistor LCT can be additionally disposed between the sensing transistor SENT and the reference voltage line.

The gate node of the load control transistor LCT can be shared with the gate node of the sensing transistor SENT and be turned on by a turn-on voltage of the sensing signal SE. According to this configuration, the reference voltage line can be electrically connected to the sensing transistor SENT only during a period in which the sensing signal SE is applied at the turn-on level.

A first capacitor Cst corresponding to a storage capacitor can be connected between the first node N1 and the second node N2. The first capacitor Cst can charge a gate-source voltage Vgs of the driving transistor DRT.

A second capacitor C2 can be connected between the second node N2 and a high voltage line to which the high voltage EVDD is applied.

The anode electrode of the light emitting element ED can be connected to the fourth scan transistor SCT4, and the cathode electrode of the light emitting element ED can be connected between a low voltage line to which a low voltage EVSS is applied.

A parasitic capacitor Coled can be formed across the light emitting element ED.

The subpixel structure of FIG. 12 including six transistors and two capacitors can be referred to as a 6T2C structure.

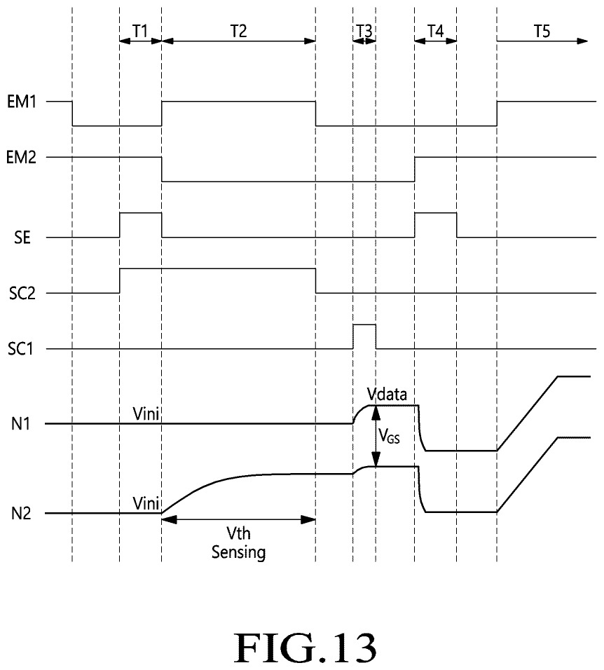

FIG. 13 illustrates signal waveforms for operating the subpixel circuit of FIG. 12.

Referring to FIG. 13, in one or more example embodiments, operation of the subpixel circuit can be performed in a period including an initialization sub-period T1, a sensing sub-period T2, a data writing sub-period T3, an anode reset sub-period T4, and an emission sub-period T5.

During the initialization sub-period T1, the subpixel circuit can be initialized.

During the sensing sub-period T2, a high voltage EVDD can be applied to the driving transistor DRT by a first emission signal EM1, and a voltage of the second node N2 of the driving transistor DRT can increase by the second capacitor C2. When the voltage of the second node N2 of the driving transistor DRT is saturated, the voltage of the second node N2 can be sampled.

During the sensing sub-period T2, one or more characteristic values of the driving transistor DRT can be sensed and stored in the first capacitor Cst. The sensing sub-period T2 can include a tracking sub-period and a sampling sub-period.

An operation for sensing and sampling one or more characteristic values of the driving transistor DRT can be defined as a compensation operation.

During the data writing sub-period T3, a data voltage Vdata can be applied to the first node N1.

During the anode reset sub-period T4, the sensing transistor SENT and the load control transistor LCT can be turned on by a sensing signal SE, and an anode reset voltage for resetting the anode electrode of the light emitting element ED can be applied through the reference voltage line.

In one or more aspects, the anode reset sub-period T4 can be omitted.

During the emission sub-period T5, a driving current can flow through the driving transistor DRT and the light emitting element ED by first and second emission signals (EM1 and EM2) of a turn-on level, so that the light emitting element ED can emit light with a luminance corresponding to a grayscale value of the data voltage Vdata.

As discussed above, the display panel 110 can provide effects or advantages of reducing the number of sensing transistors SENT connected to a reference voltage line during a period in which a sensing signal SE is applied through a load control transistor LCT in various subpixel structures for sensing characteristic values (e.g., a threshold voltage or mobility) of driving transistors DRT by using sensing transistors SENT, and thereby, reducing a load of the reference voltage line and a sensing time.

The examples, aspects, and embodiments of the present disclosure described herein will be briefly described as follows.

According to the one or more example embodiments described herein, a display panel can include a light emitting element included in each of a plurality of subpixels, a subpixel circuit for driving the light emitting element, a reference voltage line connected to a pixel group including a plurality of subpixel circuits, and a load control transistor for electrically connecting the pixel group and the reference voltage line during a period in which a gate signal is applied to the pixel group.

In one or more aspects, the subpixel circuit can include a driving transistor for driving the light emitting element, a scan transistor controlled by a scan signal and connected between a first node of the driving transistor and a data line, and a sensing transistor controlled by a sensing signal and connected between a second node of the driving transistor and the load control transistor.

In one or more aspects, the subpixel circuit can include a driving transistor for driving the light emitting element, a first scan transistor controlled by a first scan signal and transferring a data voltage to a first node of the driving transistor, a second scan transistor controlled by a second scan signal and transferring an initialization voltage to the first node, a third scan transistor controlled by a first emission signal and transferring a high voltage to a third node of the driving transistor, a fourth scan transistor controlled by a second emission signal and connecting a second node of the driving transistor and an anode electrode of the light emitting element, a first capacitor connected between the first node and the second node, a second capacitor connected between the second node and a high voltage line to which the high voltage is applied, and a sensing transistor controlled by a sensing signal and connected between the anode electrode of the light emitting element and the load control transistor.

In one or more aspects, the sensing transistor and the load control transistor can be controlled by the same sensing signal.

In one or more aspects, the load control transistor can be disposed for each pixel group.

In one or more aspects, the load control transistor can be disposed for each of a plurality of pixel lines.

In one or more aspects, the load control transistor can be disposed for each odd pixel line or each even pixel line.

In one or more aspects, the load control transistor can be disposed only in one or more pixel lines among a plurality of pixel lines.

In one or more aspects, the sensing transistor and the load control transistor can be N-type transistors.

In one or more aspects, the pixel group can include two pixels disposed on both sides of the reference voltage line.

In one or more aspects, the pixel group can include four pixels disposed on both sides of the reference voltage line.

According to the one or more example embodiments described herein, a display device can include a display panel including a plurality of subpixels, and a driving circuit configured to drive the display panel, the display panel including a light emitting element included in each of a plurality of subpixels, a subpixel circuit for driving the light emitting element, a reference voltage line connected to a pixel group including a plurality of subpixel circuits, and a load control transistor for electrically connecting the pixel group and the reference voltage line during a period in which a gate signal is applied to the pixel group.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A display panel comprising:
a light emitting element included in each of a plurality of subpixels;
a plurality of subpixel circuits each configured to drive a corresponding light emitting element;
a reference voltage line connected to a pixel group including at least some of the plurality of subpixel circuits; and
a load control transistor electrically connecting the pixel group and the reference voltage line during a period in which a gate signal is applied to the pixel group.

2. The display panel of claim 1, wherein each of at least one of the plurality of subpixel circuits comprises:
a driving transistor configured to drive the light emitting element;
a scan transistor controlled by a scan signal and connected between a first node of the driving transistor and a data line; and
a sensing transistor controlled by a sensing signal and connected between a second node of the driving transistor and the load control transistor.

3. The display panel of claim 1, wherein each of at least one of the plurality of subpixel circuits comprises:
a driving transistor configured to drive the light emitting element;
a first scan transistor controlled by a first scan signal and configured to transfer a data voltage to a first node of the driving transistor;
a second scan transistor controlled by a second scan signal and configured to transfer an initialization voltage to the first node of the driving transistor;
a third scan transistor controlled by a first emission signal and configured to transfer a high voltage to a third node of the driving transistor; and
a fourth scan transistor controlled by a second emission signal and connecting a second node of the driving transistor and an anode electrode of the light emitting element.

4. The display panel of claim 3, wherein each of at least one of the plurality of subpixel circuits further comprises:
a first capacitor connected between the first node and the second node;
a second capacitor connected between the second node and a high voltage line to which the high voltage is applied; and
a sensing transistor controlled by a sensing signal and connected between the anode electrode of the light emitting element and the load control transistor.

5. The display panel of claim 2, wherein the sensing transistor and the load control transistor are controlled by a same sensing signal.

6. The display panel of claim 1, wherein the load control transistor is disposed for each pixel group.

7. The display panel of claim 1, wherein the load control transistor is disposed for each of a plurality of pixel lines.

8. The display panel of claim 1, wherein the load control transistor is disposed for each odd pixel line or each even pixel line.

9. The display panel of claim 1, wherein the load control transistor is disposed only in one or more pixel lines among a plurality of pixel lines.

10. The display panel of claim 2, wherein the sensing transistor and the load control transistor are N-type transistors.

11. The display panel of claim 1, wherein the pixel group includes two pixels disposed on both sides of the reference voltage line.

12. The display panel of claim 1, wherein the pixel group includes four pixels disposed on both sides of the reference voltage line.

13. A display device comprising:
a display panel in which a plurality of subpixels are disposed; and
a driving circuit configured to drive the display panel,
wherein the display panel comprises:
a light emitting element included in each of the plurality of subpixels;
a plurality of subpixel circuits each configured to drive a corresponding light emitting element;
a reference voltage line connected to a pixel group including some of the plurality of subpixel circuits; and
a load control transistor electrically connecting the pixel group and the reference voltage line during a period in which a gate signal is applied to the pixel group.

14. The display device of claim 13, wherein each of at least one of the plurality of subpixel circuits comprises:
a driving transistor configured to drive the light emitting element;
a scan transistor controlled by a scan signal and connected between a first node of the driving transistor and a data line; and
a sensing transistor controlled by a sensing signal and connected between a second node of the driving transistor and the load control transistor.

15. The display device of claim 14, wherein the sensing transistor and the load control transistor are controlled by the a same sensing signal.

16. The display device of claim 14, wherein the sensing transistor and the load control transistor are N-type transistors.

17. The display device of claim 13, wherein the load control transistor is disposed for each pixel group or for each of a plurality of pixel lines.
